(19) United States
(12) Patent Application Publication
(10) Pub. No.: US 2010/0172107 A1
(43) Pub. Date: Jul. 8, 2010

(54) Device for Determining and/or Monitoring a Process Variable

(75) Inventors: Georg Wolf, Marktoberdorf (DE); Detlef Schuttenberg, Kaufbeuren (DE); Andreas Martin, Nesselwang (DE)

Correspondence Address: BACON & THOMAS, PLLC, 625 SLATERS LANE, FOURTH FLOOR, ALEXANDRIA, VA, 22314-1176, US

(73) Assignee: Endress+Hauser Wetzer GmbH+Co. KG, Nesselwang (DE)

(21) Appl. No.: 12/602,365

(22) PCT Filed: Jun. 4, 2008
(86) PCT No.: PCT/EP08/56881

§ 371 Date: Nov. 30, 2009

(30) Foreign Application Priority Data
Jun. 5, 2007 (DE) 10 2007 026 498.6

(51) Int. Cl. H05K 5/00

(52) U.S. Cl. 361/724

(57) ABSTRACT

An apparatus for determining and/or monitoring at least one process variable. The apparatus comprises at least one housing, which has at least a housing lower part and a housing lid. The housing lower part and the housing lid are connected together by at least one connecting element.

The invention relates to an apparatus for determining and/or monitoring at least one process variable. The apparatus comprises at least one housing, which has at least a housing lower part and a housing lid. The process variable is, for example, temperature, fill level, pressure, density, viscosity, conductivity, moisture, pH value or flow, e.g. flow rate.

In the state of the art, a series of measuring devices are known, which serve for measuring or monitoring process variables. These measuring devices are most often comprised of a sensor element, which produces a measured variable dependent on the process variable or a change of the process variable. The sensor element and the electronics serving for operation or further processing of the measured variable are most often arranged in a housing (designations include: “Instrument housing” or “field housing”), which often is composed of a lower part and a lid. For the purpose of preventing loss of such lids, for example, steel chains, secured by screws, extend between the housing lower part and the lid. In such case, there is the danger of hooking the chain on grip contours or other projecting elements. Moreover, there is the danger that the chain, during the screwing on or off of the lid or through vibration of the plant during operation, can cause wear of the surface, or the surface coating, of the housing.

At times, e.g. during connecting or start-up of the measuring device, it is necessary to open the lid. Since the measuring devices, in given cases, are mounted at poorly accessible or elevated locations, a lid loss preventer is very advantageous. During operation of the measuring device, it is, furthermore, in the case of maintenance tasks or, in given cases, in the case of reparametering of the measuring point, necessary to open the lid, in order to reach the internally lying electronics of the measuring device.

An object of the invention is to provide a measuring device with a lid loss preventer avoiding the disadvantages of the state of the art.

The invention achieves the object by the features that the housing lower part and the housing lid are connected with one another by at least one connecting element. The connecting element is, in such case, embodied in such a manner, that it is suitable, for example, for the arising environmental conditions, such as e.g. temperature, or, for example, also relative to the material of the housing.

An embodiment provides that the connecting element contacts the housing lower part and the housing lid. The connecting element is, thus, connected both with the housing lower part, as well as also with the housing lid.

An embodiment is fashioned in such a manner, that the connecting element contacts an inside of the housing lower part and an inside of the housing lid. Especially, the connecting element is located, thus, completely in the interior of the housing.

An embodiment includes that the connecting element is embodied in such a manner and contacts the housing lower part and the housing lid in such a manner that the housing lower part and the housing lid are rotatable relative to one another. Especially, the housing lower part and the housing lid have corresponding screw threads, so that they can be screwed together.

An embodiment provides that at least one groove is provided in the housing lower part and/or in the housing lid, and that the connecting element contacts the housing lower part and/or the housing lid at least via the groove. Preferably, the groove is a completely surrounding groove, so that the connecting element does not hinder the screwing together and the unscrewing of the two components of the housing.

An embodiment is fashioned in such a manner, that, in the housing lower part and in the housing lid, in each case, at least one groove is provided, and that the connecting element contacts the housing lower part and the housing lid at least via the two grooves. Thus, at least two grooves are provided, of which one is located in the housing lower part and the other in the housing lid.

An embodiment includes that the groove is arranged on an inside of the housing lower part or of the housing lid. Since the groove is located on the inside and when, moreover, also the second contacting by the connecting element is on an inside of the housing, the connecting element is always accommodated inside and it is possible then to have a correspondingly smooth outside of the housing, so that this variant is relevant and advantageous especially in the case of hygienic applications. In an embodiment, the connecting element is connected fixedly at one end to the housing lower part or the housing lid at one position and the other end of the connecting element permits, via the contacting in the groove in the housing lid, or in the housing lower part, the turning of lower part and lid relative to one another.

An embodiment provides that the groove is arranged in an outer surface of the housing lower part or the housing lid. The contacting via a groove permits, in a corresponding embodiment of the connecting element, the rotation of lid and lower part relative to one another.

An embodiment includes that at least one ring is provided, and that the ring is accommodated rotatably in the groove. A ring serves for simple securement of the connecting element. If the ring is, moreover, embodied and coordinated with the groove in such a manner, that it can slide in the groove, then also the rotation of lower part and lid relative to one another can be effected in combination with the connecting element.

An embodiment is fashioned in such a manner that the ring contacts the connecting element. In an additional embodiment, the ring and the connecting element are embodied as one-piece. In an additional embodiment, the connecting element is connected releasably with the ring.

An embodiment provides that the ring has a plug, that the connecting element has an opening, and that the ring and the connecting element are connected together at least via the plug and the opening. The opening in an embodiment is embodied in such a manner, that it is easier to engage with the plug in one direction than in an opposing direction, so that a securement of the connecting element to the ring is realized.

An embodiment includes that the connecting element is embodied mechanically flexibly.

An embodiment provides that the connecting element is composed of a synthetic material.

An embodiment includes that at least one cable duct is provided. Such a cable duct serves, for example, for the introduction of a cable for contacting or for energy supply of the measurement transmitter in the measuring device. In the state of the art, for example, curved tube pieces are used. The cable duct serves, thus, for connection between the interior of the housing and its outer region.

An embodiment provides that the cable duct is an integral component of the housing lower part. The cable duct is, thus, a fixed component of the housing lower part.

In the state of the art there are, for example, curved tube pieces, which serve to guide the cable and which, in given cases, are composed of a plurality of individual parts, which must be connected with one another and with the housing. In this embodiment, the cable duct is a fixed component of the housing. This is achieved, for example, by producing the housing lower part with the cable duct in the injection molding method, as an aluminum die casting, as a stainless steel, lost wax casting or as a deep drawn part. Especially, this embodiment can also be applied without the loss preventer.

An embodiment includes that the cable duct is embodied in such a manner, that a cable entrance and a cable exit of the cable duct have essentially an angle of 90° relative to one another. Especially, the axial elongations of the cable entrance and the cable exit form essentially an angle of 90° relative to one another. The cable is guided in such a manner, that it does not disturb the outside of the housing—thus, especially, it is not found in the region of a display.

An embodiment provides that the cable duct has at least one incline, which is embodied in such a manner, that the incline steers a cable moving from the entrance of the cable duct in the direction of the cable exit. The incline and the cable duct have in such case especially no sharp transitions. Especially, the cable duct is embodied in such a manner, that the cable is guided essentially kink free. Furthermore, the cable duct is preferably embodied via the incline in such a manner, that the cable can be inserted into the duct without special tools and emerges on the oppositely lying side, wherein especially a pushing force on the cable is sufficient to accomplish this.

An embodiment includes that at least one display unit is provided, which is arranged in the housing lid. Such a display unit serves, for example, for the simple display of whether the measured value for the process variable still lies within a specified range. It is, thus, for example, a status display output. However, also more extensive display functions are possible.

An embodiment provides that the display unit includes at least one LED display. Such an LED display is composed in the simplest case of one or more LED units, which are suitably driven.

An embodiment includes that the display unit includes at least one light guide plug in a wall of the housing lid. In an embodiment, at least one LED unit is located on a circuit board, which is connected correspondingly with an evaluation unit in the measuring device. Contacted with the LED unit is a light guide plug, which is accommodated at least partially in a wall of the housing lid.

The invention will now be explained in greater detail on the basis of the appended drawing, the figures of which show as follows:

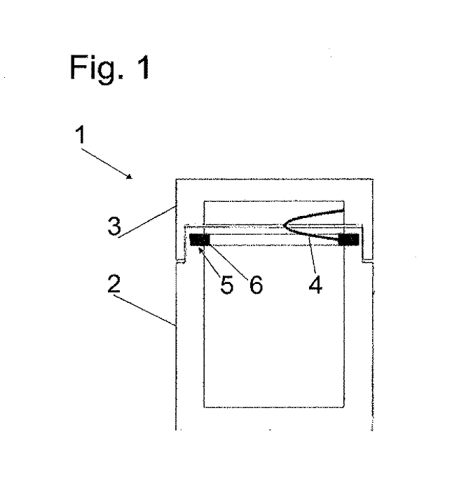

FIG. 1 a section through a first variant of a measuring device of the invention, with closed housing;

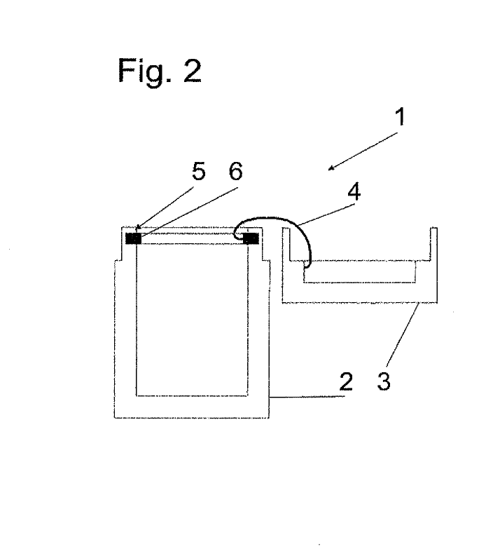

FIG. 2 a section through the device of FIG. 1, with opened housing;

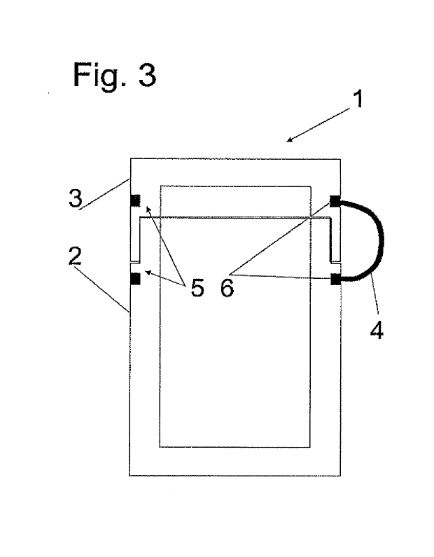

FIG. 3 a section through a second variant of the measuring device of the invention, with the closed housing;

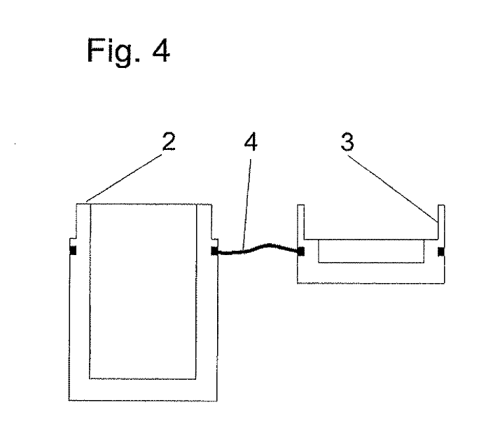

FIG. 4 a section through the device variant of FIG. 3, with opened housing;

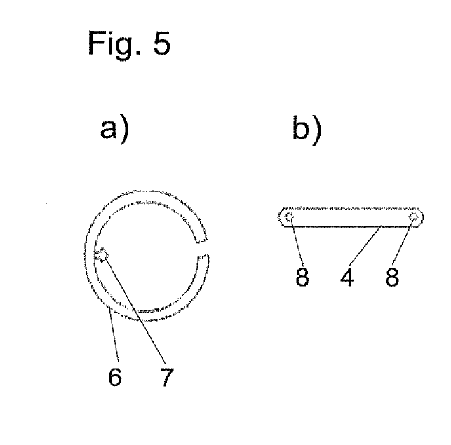

FIGS. 5a,b plan views of the ring and the connecting element, respectively;

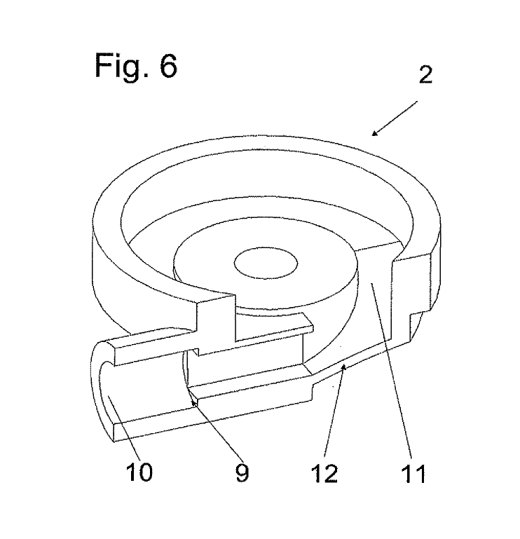

FIG. 6 a partially sectioned, three dimensional drawing of the housing lower part showing the cable duct; and

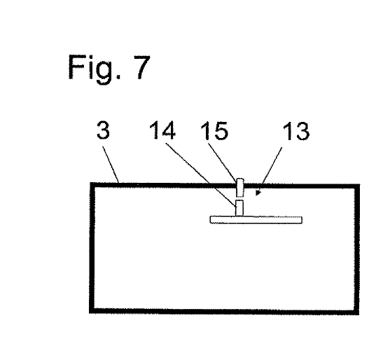

FIG. 7 a section through a housing lid containing the display unit.

FIG. 1 shows a section through a schematic drawing of the measuring device of the invention for determining and/or monitoring at least one process variable of a first variant. The process variable is, for example, temperature, fill level, pressure, density, viscosity, conductivity, moisture, pH value or flow, for example, of a medium, such as, for example, a liquid, a gas, a bulk good or a mixture thereof.

The temperature head housing shown here is a component of a complete thermometer. Accommodated in the temperature head housing are the electronics of the thermometer. A temperature head housing can be made of synthetic material, aluminum or stainless steel. For hygienic applications, housings of stainless steel are applied. Most often connected to this upper part is a protective tube for the actual temperature sensor.

The housing 1 is composed of a housing lower part, or housing base, 2 and a housing lid 3. In such case, the lower part 2 and the lid 3 are provided, for example, with matching internal and external thread in such a manner that they can be screwed together. Serving as lid loss preventer 3 is the connecting element 4, which is preferably flexibly embodied, thus, for example, is composed of a synthetic material. In this embodiment, furthermore, the lower part 2 and the lid 3 are, at least in the region, in which they are to be connected with one another, cylindrically embodied.

In the here illustrated variant, on the inside of the housing lower part 2, a surrounding groove 5 is provided, in which a ring 6 is placed. Secured to the ring 6 is the connecting element 4. The ring 6 and the groove 5 are in such case embodied in such a manner, that the ring 6 is held rotatably in the groove 5. On the other side, the connecting element 4 is connected with the lid 3. The rotatable ring 6 permits, that the lid 3 can be rotated relative to the lower part 2, while the connecting element 4 remains affixed. In this variant, the connecting element 4 is connected both with the inside of the lower part 2, as well as also with the inside of the lid 3. Thus, the connecting element 4 is always located within the housing 1 and, at least when the housing 1 is closed, there can be no fouling of the connecting element 4. Thus, this variant is especially applicable for hygienic applications, since the housing 1 can be embodied in such a manner, that it is, as much as possible, gap free, without edges and with smooth geometry on the outer surfaces, so that neither dirt, nor impurities can collect on the outside of the housing. The advantage of this embodiment lies, thus, in the smooth and gap free embodiment of the outer surface of the housing, despite presence of the loss preventer.

FIG. 2 shows the measuring device with opened housing 1. As can be seen, the lid 3 is connected loss safely with the lower part 2 via the connecting element 4.

FIG. 3 shows a second variant of the measuring device, in the case of which the connecting element 4 is secured both to the lid 3, as well as also to the lower part 2 via in each case a ring 6 and simultaneously is rotatable in the grooves 5 in the housing lower part 2 and in the housing lid 3, respectively. The two rings 6 and the connecting element 4 are embodied here as one piece. In an additional embodiment, the connecting element 4 includes on at least one end a thickening, which permits it to fit into the groove 5 fit and simultaneously still to slide in it. The connecting element 4 and the ring, or rings, 6 are, for example, plastic, molded parts. Used as injected material can be e.g. an elastomer, especially a thermoplastic elastomer. It is, in such case, to be heeded that the material have sufficient sliding properties, in order to slide against the housing, or in the respective grooves, while, on the other hand, however, being elastic enough, in order that the lid 3 can also be rotated to the side for opening, and, for example, assembly is assured. Alternatively to the elasticity, another option is to design a plastic, formed part such that it is sufficiently movable (e.g. a film hinge).

Through the invention, thus, there is no longer the danger of the hooking and, thus, hindering, when screwing the lid 3 on or off. Moreover, also damaging of the surface is avoided.

FIG. 4 shows the housing 1 of the second variant illustrated in FIG. 3, in the opened state, i.e. the lid 3 has been screwed off of the housing lower part 2 and is held securely by the connecting element 4.

FIG. 5 shows a rotatable ring 6 (FIG. 5a)), as well as a flexible connecting element 4 (FIG. 5b)), such as are applicable in the measuring device of the invention.

The ring 6 includes a plug 7, via which it can be plugged into an opening 8 of the connecting element 4. Alternatively, a screwed connection is provided in the ring 6.

The second opening 8 of the connecting element 4 serves, for example, for the securement of the connecting element 4 (e.g. via a similar plug such as on the ring 6) to the lid, or to the housing lower part, as the case may be. Ring 6 has, furthermore, an opening permitting compressing for assembly. Connecting element 4 is, for example, a plastic strip. Connecting element 4 is, in an embodiment, in each case, connected with a ring, wherein a first ring is located in a groove in the housing lower part and a second ring is located in a groove in the housing lid.

FIG. 6 shows a part of a housing lower part 2. Shown is the cable duct 9 for guiding a cable, which, for example, is for connection with the measurement transmitter (not shown). The measurement transmitter is in such case to be placed in the upper opening of the housing lower part 2. The measurement transmitter serves in such case, for example, for operating the measuring sensor and/or for evaluation or further processing of the measured values from the sensor as regards the process variable.

The cable entrance 10 lies below the receptacle for the measurement transmitter. The axial elongations of cable entrance 10 and cable exit 11 in the inner part of the housing form an angle of 90° relative to one another. The incline 12 is embodied in such a manner, that the cable is inserted by an easy pushing into the interior, wherein, especially, it is prevented, that the cable can be kinked. I.e., no special tools are necessary, in order to draw the cable, for example, into the inner space; it is sufficient that the cable be introduced into the cable entrance 10 and then pushed in. Thus, contacting and wiring are also very much simplified.

The arc formed by the incline 12 has, in such case, a radius, which is as large as possible, so that a simple guiding of the cable inwards is further supported thereby. The cable exit 11 has, here, a large opening, while the incline 12 has an angle of about 45°. The angle of the cable duct 9 is, in such case, matched in such a manner to the embodiment of the housing, that the cable is turned in the direction of the cable exit 11, or the opening of the housing basin. The lower the housing lower part 2, the shallower the angle can be. The cable end exits then at a corresponding angle from the housing opening. Important, in such case, is that the emergence of the cable can be accomplished by the pushing and that essentially no additional tools are required.

FIG. 7 shows the upper side of the housing lid 3. Shown is the end of the light guide plug 15, which is a part the display unit 13 and which conducts the signal of at least one LED 14 from the inside of the housing outwardly. Such a simple display unit 13 serves, for example, for the transmission of status signals, so that on-site monitoring of the process variable is simplified.

### LIST OF REFERENCE CHARACTERS

1 housing
2 housing lower part
3 housing lid
4 connecting element
5 groove
6 ring
7 plug
8 opening
9 cable duct
10 cable entrance
11 cable exit
12 incline
13 display unit
14 LED display
15 light guide plug

1.-10. (canceled)

11. An apparatus for determining and/or monitoring at least one process variable, comprising:
at least one housing, which has at least a housing lower part and a housing lid;
and at least one connecting element, wherein:
said housing lower part and said housing lid are connected together by said at least one connecting element, said connecting element contacts an inside of said housing lower part and an inside of said housing lid; and
said connecting element is embodied in such a manner and contacts said housing lower part and said housing lid in such a manner, that said housing lower part and said housing lid are rotatable relative to one another.

12. An apparatus as claimed in claim 11, further comprising:
at least one groove in said housing lower part and/or in said housing lid; and
said at least one connecting element contacts said housing lower part and/or said housing lid at least via said at least groove.

13. The apparatus as claimed in claim 11 further comprising:
at least one groove in each case, in said housing lower part and in said housing lid; and
said at least one connecting element contacts said housing lower part and said housing lid at least via said two grooves.

14. An apparatus as claimed in claim 12 wherein:
said groove is arranged inside said housing lower part or said housing lid.

15. The apparatus as claimed in claim 12 further comprising:
at least one ring, said at least one ring is accommodated rotatably in said at least one groove, and said connecting element contacts said ring.

16. An apparatus as claimed in claim 15, wherein:
said ring has a plug, said connecting element has an opening, and said ring and said connecting element are contacted together at least via said plug and said opening.

17. The apparatus as claimed in claim 11, wherein:
said at least one connecting element is embodied mechanically flexibly.

18. The apparatus as claimed in claim 11, wherein:
said at least one connecting element comprises a synthetic material.

19. The apparatus as claimed in claim 11 further comprising:
at least one cable duct, said at least one cable duct is an integral component of said housing lower part, and said at least one cable duct has at least one incline, which is embodied in such a manner, that said incline steers a cable introduced into said at least one cable duct toward a cable exit.

20. The apparatus as claimed in claim 11 further comprising:
at least one display unit which is arranged in said housing lid, said at least one display unit has at least one light guide plug in a wall of said housing lid, which conducts the signal of an LED display.
